(19) United States
(12) Patent Application Publication
(10) Pub. No.: US 2007/0183191 A1
(43) Pub. Date: Aug. 9, 2007

(54) Stacked capacitor memory

(75) Inventor: Juhan Kim, San Jose, CA (US)

Correspondence Address: JUHAN KIM, 5890 W. WALBROOK DR., SAN JOSE, CA, 95129, US

(73) Assignee: Juhan Kim, San Jose, CA (US)

(21) Appl. No.: 11/615,936

(22) Filed: Dec. 23, 2006

Related U.S. Application Data
(63) Continuation of application No. 11/307,318, filed on Feb. 1, 2006.

(51) Int. Cl. G11C 15/00; G11C 11/36; G11C 11/24

(52) U.S. Cl. 365/175; 365/149; 365/49

(57) ABSTRACT

Stacked capacitor memory is realized, wherein a capacitor stores data and a diode serves as an access device instead of MOS transistor, the first terminal is connected to a word line, the second terminal is connected to the first electrode of the capacitor which serves as a storage node while the second electrode is connected to a plate line, the third terminal is floating, and the fourth terminal is connected to a bit line. When write, the storage node is charged or not, depending on the conducting state of the diode which is controlled by the bit line. When read, the diode also serves as a sense amplifier to detect whether the storage node is forward bias or not, and it sends binary data to a latch device wherein includes a current mirror and a feedback loop which cuts off the current path after latching, thus it reduces active current, minimizes data pattern sensitivity, and also rejects coupling noise. And dummy rows and columns generate replica delay signals which guarantee timing margin and reduce cycle time. And its applications are extended to single port, multi port and content addressable memory. In addition, the memory cells are formed in between the routing layers, which memory cells can be stacked over the transistor or another capacitor memory cell.

### FIELD OF THE INVENTION

The present invention relates generally to integrated circuits, in particular to RAM (Random Access Memory) including capacitor storage element, and its applications, such as single port memory, multi port memory and CAM (content addressable memory).

### BACKGROUND OF THE INVENTION

A p-n-p-n diode known as Shockley diode or thyristor, is a solid-state semiconductor device similar to two-terminal p-n diode, with an extra terminal which is used to turn it on. Once turned on, diode (p-n-p-n diode or n-p-n-p diode) will remain on conducting state as long as there is a significant current flowing through it. If the current falls to zero, the device switches off. Diode has four layers, with each layer consisting of an alternately p-type or n-type material, for example p-n-p-n and n-p-n-p. The main terminals, labeled anode and cathode, are across the full four layers, and the control terminal, called the gate, is attached to one of the middle layers. The operation of a diode can be understood in terms of a pair of tightly coupled transistors, arranged to cause the self-latching action.

Diodes are mainly used where high currents and voltages are involved, and are often used to control alternating currents, where the change of polarity of the current causes the device to automatically switch off; referred to as ‘zero cross operation’. The device can also be said to be in synchronous operation as, once the device is open, it conducts in phase with the voltage applied over its anode to cathode junction. This is not to be confused with symmetrical operation, as the output is unidirectional, flowing only from anode to cathode, and so is asymmetrical in nature. These properties are used control the desired load regulation by adjusting the frequency of the trigger signal at the gate. The load regulation possible is broad as semiconductor based devices are capable of switching at extremely high speeds over extremely large numbers of switching cycles.

In FIG. 1A, the schematic of diode is illustrated. It consists of four terminals, such that the anode 111 is connected to power supply or regulating node, the base 112 of p-n-p transistor 115 serves as the collector 112 of n-p-n transistor 114, the collector 113 of p-n-p transistor 115 serves as the base of n-p-n transistor 114 which is controlled by the voltage controller 116. In order to turn on diode and hold the state of turn-on, the voltage controller should raise the voltage from ground level to VF (forward bias, 0.6 v˜0.8 v for silicon). And the voltage controller 116 should supply the current 117, referred as the base current, which current depends on the characteristic of transistor 114 and 115. Once the base current 117 establishes the forward bias (VF), the collector 112 of n-p-n transistor 114 holds the current path 119 from the base of p-n-p transistor 115. After then, p-n-p transistor 115 is turned on because the base 112 has forward bias from the emitter 111. This makes the current path 118 which can keep the turn-on state. This is the holding state as long as the base has not so much leakage to drive the base voltage under forward bias (VF) even though the voltage controller 116 is open. To turn off diode, the voltage controller 116 should lower the voltage of the base of n-p-n transistor 114 under forward bias. To do so, the voltage controller 116 should (negatively) flow more current than the current path 118.

Diode can hold the states of turn-on or turn-off, but it has very high holding current to store ‘on’ state. There are many prior arts to apply diode to a capacitive memory devices, such as, “High density planar SRAM cell using bipolar latch-up and gated diode breakdown”, U.S. Pat. No. 6,104,045, and “Thyristor-type memory device” U.S. Pat. No. 6,967,358 and “Semiconductor capacitively-coupled negative differential resistance device and its applications in high-density high-speed memories and in power switches”, U.S. Pat. No. 6,229,161. These prior arts require very high holding current and multiple internal voltage generators, in order to use a diode itself as a holding device which becomes a memory cell. And there is another report, “A novel capacitor-less DRAM cell Thin Capacitively-Coupled Thyristor (TCCT)”, 2005 IEEE Electron Devices Meeting (IEDM) Tech. Dig. pp. 311. This approach requires very deep negative voltage in order to write data because the inversion layer of the gate is attached to the drain/source region (or emitter/collector), the gate can swing only ground to deep negative voltage (−1.5V) to avoid the leakage path to the drain, which needs negative pump circuit or external negative voltage. And high current flowing eventually raises operating temperature by “Joule heating”, which produces more junction leakage and gate leakage. Consequently, the data stored in the diode can be lost quickly by those leakages.

Another approach is that diode replaces the MOS access device as a switching element, not holding device. However diode can not easily replace the MOS device as an access device because it has unidirectional current control characteristic and internal feedback loop. Now the present invention devotes to replace MOS transistor with a diode as an access device and a control methodology has been invented to control the diode for memory operation. Diode can work for the memory devices as a switching element, not a storage element. Furthermore, diode can replace sense amplifier as well, such that diode output generates information “on” or “off” which is digital value. It gives as many as advantages to design and fabricate it on the wafer.

Separately a capacitor is still required to store data as the conventional memories such as DRAM (Dynamic Random Access Memory) and FRAM (Ferroelectric Random Access Memory), but now there is no need of high capacitance to drive the bit line directly. Instead, the capacitor drives only one of diode terminals which has very little capacitance, and the capacitor indirectly communicates to the bit line (or data line), while diode directly communicates to the bit line. As a result, diode serves as a sense amplifier to detect whether the storage node voltage is forward bias or not. This is different control method from the conventional DRAM, where the gate of MOS transistor is connected to the word line and turns on and off, but the load of the word line is only gate and routing capacitance, while the storage capacitor drives the very heavy the bit line directly, which means that the word line loading is very light, in the conventional DRAM. Conversely, using diode as an access device gives the bit line loading to the word line through diode, which makes the word line loading very heavy, but it is controllable to design with strong driver or segmentation for the word line. Even though the word line loading is high, it is desirable to configure a memory array because the word line driver is stronger than the weak storage capacitor. In the conventional DRAM, the weak storage capacitor directly drives the bit line, which needs time to redistribute charge from the capacitor to the bit line. The stored charge was lost during read cycle by the charge redistribution, which is referred as destructive read. Memory read cycle was very slow because each read cycle requires additional restore procedure.

Furthermore, the word line should be higher level than that of the bit line to reduce threshold voltage drop by the access NMOS transistor. In case of PMOS access transistor, the word line should be negative during write or restore. Those consume high switching current and pumping current. And MOS access transistor has subthreshold leakage current which is tricky and hard to reduce. In order to reduce subthreshold leakage current, the body of the MOS transistor is applied negative voltage for NMOS transistor, but the internal negative voltage generator consumes current and needs to be adjusted for the optimum voltage level for the use. And one more undesirable effect is the parasitic bipolar transistor in the bottom side of the MOS transistor which should be suppressed by applying the negative voltage to the body. The slight forward bias can remove the stored charge to the body.

Applying a diode as an access device, memory array design has a lot of freedom escaping from the MOS device. Additionally, the capacitor can be reduced, and any of capacitor can be used for storing data. Depending on the capacitor material, the retention time and the write time are different. For example, DRAM uses ordinary dielectric capacitor, such as silicon dioxide, silicon nitride, Ta₂O₅, TiO₂, Al₂O₃, TiN/HfO₂/TiN(TIT), and Ru/Insulator/TiN(RIT), which can store data in the range of 300 ms to 1 sec. It is called volatile memory. Alternatively, ferroelectric capacitor can be used as a storage capacitor, such as lead zirconate titanate (PZT), lead lanthanum zirconium titanate (PLZT), barium strontium titanate (BST), and strontium bismuth tantalate (SBT), as shown in the prior art, “Ferroelectric Random-Access Memory”, U.S. Pat. No. 5,600,587. In the present invention, ferroelectric capacitor can be used as a volatile memory because the stored charges are gradually discharged after the electric field is off. Moreover read operation is different from FRAM (Ferroelectric Random Access Memory), such that the plate line is not moving, when read, in the present invention, while the plate line moves in the FRAM operation in order to measure the polarized charges in the ferroelectric capacitor. Thus the memory operation is still volatile mode, but retention time would be increased as long as high dielectric constant material is used.

In the prior art, the storage capacitor directly drives the heavily loaded bit line through the MOS transistor, which means that read operation depends on the charging time of the weak storage capacitor to heavily loaded bit line. Also turn-on resistance of the MOS transistor is higher than that of diode. Thus discharging is slow with high RC time constant. These are major disadvantages of DRAM operation. Moreover read operation is destructive which requires the write-back operation. In consequence, DRAM operation is very slow.

Still, there is a need in the art for a memory circuit and cell for random access memory devices, which realize low power, high density and simple structure to fabricate on the wafer. In the conventional MOS access transistor as shown in FIG. 1B, there is a parasitic n-p-n bipolar transistor wherein the body 134 serves as the base, source/drain serve as the emitter/collector. During read and write cycle, the base (body) 134 is at ground (or negative) to prevent bipolar effect. The parasitic bipolar transistor is not wanted device in the conventional memories which is usually turned off, but now adding one more terminal to the parasitic bipolar transistor in the conventional memory, a p-n-p-n diode (or n-p-n-p) can serve as four-terminal diode access device for the next generation memory devices with good performance and simple structure. Separately, storage capacitor is required to store data, but there is no need of high capacitance because the storage capacitor only drives the base of bipolar transistor while strong diode drives heavily loaded bit line.

### SUMMARY OF THE INVENTION

In the present invention, stacked capacitor memory is realized, wherein the memory cell is formed in between the routing layers on the wafer in order to reduce chip area. Also the memory cell can be formed on the MOS transistor because the memory cell includes a four-terminal diode access device and a storage capacitor, which combination is less complicated to fabricate with additional process steps in the current CMOS process environment, compared to fabricating the conventional memory including the MOS transistor as an access device.

Diode need not be a high performance device nor have a high current gain, and diode also serves as a sense amplifier to detect the voltage of the storage node whether it is forward bias or not, then diode sends binary results to the bit line, and the latch device including the current mirror receives the binary results from the bit line, on or off. The current mirror repeats the amount of current that the memory cell flows, and latches the result. After latching data, the output of the latch device cuts off the current path of the bit line, which reduces active current, minimizes data pattern sensitivity, and rejects coupling noise. And the diode-based memory realizes fast access time, and does not require reference bit line. Furthermore, dummy rows and dummy columns generate replica delay signals which guarantee internal timing margin and reduce operation cycle time. In addition, diode can flow more current than MOS transistor, because the current path of diode includes its whole junction area while the current path of MOS transistor includes the shallow inversion layer on the surface by the electric field.

Furthermore, any of capacitor can be used for storing data, such as ordinary dielectric capacitor and ferroelectric capacitor. Both capacitors can be used as a volatile memory because the stored charges are gradually discharged after the electric field is off because read operation is different from FRAM (Ferroelectric Random Access Memory), such that the plate line is not moving when read in the present invention, while the plate line moves in FRAM operation in order to measure the polarized charges in the capacitor. Thus the memory operation is still volatile mode, but retention time would be increased as long as high dielectric constant material is used. However there is no need of high capacitance to drive the bit line directly because the capacitor drives a lightly loaded base of the diode while the diode drives heavily loaded bit line during read.

Furthermore, the word line cuts off the holding current during standby. Thus there is almost no standby current in the memory cell, which realizes low power consumption.

Furthermore, the applications of the present memory cell are extendable for single port memory, multi port memory and content addressable memory.

However the operation of diode is not as simple as that of MOS access transistor because it has unidirectional current control characteristic and internal feedback loop, even though it has almost no parasitic effect. In the present invention, sophisticated circuit techniques are introduced to use a diode as an access device for the capacitor memory, and the memory cell structure is simplified in between the routing layers with no MOS transistor and no extremely thin layers, in order to fabricate within the current CMOS environment.

These and other objects and advantages of the present invention will no doubt become obvious to those of ordinary skill in the art after having read the following detailed description of the preferred embodiments which are illustrated in the various drawing figures.

### BRIEF DESCRIPTION OF THE DRAWINGS

The accompanying drawings which are incorporated in and form a part of this specification, illustrate embodiments of the invention and together with the description, serve to explain the principles of the invention.

FIG. 1A illustrates a p-n-p-n diode as a prior art. FIG. 1B depicts the schematic of the conventional DRAM and FRAM, as prior arts.

FIG. 2A illustrates the basic schematics of capacitor memory and data latch as the present invention. In FIG. 2B, a series capacitor is illustrated as an equivalent capacitor for the capacitor memory application as the present invention.

FIG. 3A illustrates a timing diagram when the word line is asserted, according to the teachings of the present invention. FIG. 3B illustrates I-V curve of the memory cell, according to the teachings of the present invention. FIG. 3C illustrates I-V curve of conventional bipolar transistor is illustrated as a reference.

FIG. 4A illustrates more detailed read path, according to the teachings of the present invention. FIG. 4B illustrates the relationship between voltage and temperature of the memory cell, according to the teachings of the present invention. FIG. 4C illustrates I-V curve of pull-down NMOS transistor, according to the teachings of the present invention. FIG. 4D illustrates I-V curve of the diode access device, according to the teachings of the present invention. And FIG. 4E illustrates I-V curve of pull-up PMOS of row decoder, according to the teachings of the present invention.

FIG. 5A illustrates a timing diagram of read “1” operation, according to the teachings of the present invention. And FIG. 5B illustrates a timing diagram of read “0” operation, according to the teachings of the present invention.

FIG. 6A illustrate the schematic for reset operation, according to the teachings of the present invention. And FIG. 6B illustrates the schematic for set operation, according to the teachings of the present invention.

FIG. 7A illustrates a timing diagram for writing data “1” in view of FIG. 6A and 6B, according to the teachings of the present invention. FIG. 7B illustrates a timing diagram for writing data “0” in view of FIG. 6A and 6B, according to the teachings of the present invention.

FIG. 8A, 8B, 8C and 8D illustrate an example of array configuration, according to the teachings of the present invention.

FIG. 9 illustrates read-write circuit and memory cell, according to the teachings of the present invention.

FIG. 10 illustrates row control circuit and row decoder circuit, according to the teachings of the present invention.

FIG. 11 illustrates column control circuit and column decoder circuit, according to the teachings of the present invention.

FIG. 12A and 12B illustrate more detailed read operation with the timing diagram, according to the teachings of the present invention.

FIG. 13 illustrates an example of multi-port memory application including the invented capacitor memory.

FIG. 14 illustrates an example configuration for content addressable memory including the invented capacitor storage memory.

FIG. 15 provides a truth table summarizing the logical relationships among various signals for content addressable memory, as shown in FIG. 14.

FIG. 16A to 16C illustrate a process flow to form a stacked capacitor memory, according to the teachings of the present invention.

FIG. 17 illustrates a cross sectional view of stacked capacitor memory on the MOS transistor, according to the teachings of the present invention.

FIG. 18 illustrates a cross sectional view wherein two capacitors are stacked on the wafer, according to the teachings of the present invention.

FIG. 19 illustrates a cross sectional view wherein the bit lines are separated to reduce parasitic capacitor, according to the teachings of the present invention.

### DETAILED DESCRIPTION OF PREFERRED EMBODIMENT(S)

Reference is made in detail to the preferred embodiments of the invention. While the invention is described in conjunction with the preferred embodiments, the invention is not intended to be limited by these preferred embodiments. On the contrary, the invention is intended to cover alternatives, modifications and equivalents, which may be included within the spirit and scope of the invention as defined by the appended claims. Furthermore, in the following detailed description of the invention, numerous specific details are set forth in order to provide a thorough understanding of the invention. However, as is obvious to one ordinarily skilled in the art, the invention may be practiced without these specific details. In other instances, well-known methods, procedures, components, and circuits have not been described in detail so that aspects of the invention will not be obscured.

Detailed descriptions for the present invention are described as follows, which include the schematics, the timings and cross sectional views.

In FIG. 2A, capacitor memory is illustrated as the present invention, wherein capacitor storage element 207 stores data, and four-terminal diode serves as an access device instead of MOS transistor, the first terminal 202 is p-type and connected to a word line (WL) 201 to activate the memory cell, the second terminal 203 is n-type and connected to one electrode of the capacitor 207 which serves as a storage node, the third terminal 204 is p-type and floating, the fourth terminal 205 is n-type and connected to a bit line 206 to write or read data, and the plate line (PL) 208 is connected to another electrode of the capacitor 207. Unlike MOS access device, the diode is turned on or off, depending on the stored data during read cycle, which is quite different from the conventional switching concept to access the memory cell, such that the diode access device is turned on only if the storage node 203 is near ground. In contrast, the conventional MOS access device is turned on by the inversion layer (not shown), regardless of the stored data.

In order to read data “1” from the storage node 203, the word line 201 is raised from ground level by the pull-up PMOS 221 of the word line driver, when row decoder signal 220 is asserted to ground level, wherein the supply voltage of the word line driver 221 is VP level to write data “0”. And the data latch 230 is powered by VH level. Thus dual positive supplies are used for the memory operation. The first positive supply VP level is higher than the second positive supply VH level, which operation will be explained as below for the write operation. When the word line 201 is reached to VFP level (built-in voltage of p-n-p transistor Q1), p-n-p transistor Q1 is turned on if the storage node voltage 203 is near ground level. By turning on p-n-p transistor Q1, the collector 204 (floating node) of p-n-p transistor Q1 is raised and reached near the word line voltage from ground level. At the same time, n-p-n transistor Q2 is turned on, because the collector 204 of p-n-p transistor Q1 serves as the base 204 of n-p-n transistor Q2. Turning on p-n-p transistor Q1 and n-p-n transistor Q2, the emitter 205 of n-p-n transistor is raised by the current. Thus the bit line 206 is raised from ground level, where the initial voltage of the bit line 206 is set to ground level by NMOS 232 with pre-charge true (PT) signal. After initializing, pre-charge true (PT) signal is lowered to ground level. When the bit line 206 is reached to the threshold voltage (VTN) of the pull-down NMOS 233, pull-down device 233 is turned on, when the switch 231 is turned on by the inverter 239 which is driven by the latch node 236, where the latch node 236 is set by pre-charge-bar (PB) signal. As a result, the current path is set up from the word line 201 to the bit line 206, which is read “1” operation. Hence, the word line 201 indirectly turns on n-p-n Q2 through p-n-p Q1. In other words, diode access device detects whether the storage node is at forward bias or not. In this manner, the diode access device serves as a sense amplifier when read. After the current path is set up, the word line voltage is determined by the result of the voltage dividing among the elements, the pull-down NMOS 233, the four-terminal diode, pull-up PMOS 221, and routing resistance.

As a result, the word line voltage is near the sum of the bit line voltage and built-in voltage of the diode because the pull-down NMOS 233 has low resistance with common gate-drain connection like diode connection, which determines the bit line voltage, and four-terminal diode (including p-n-p Q1 and n-p-n Q2) has lower resistance, where the pull-up PMOS 221 has high resistance at linear region, and routing resistance is negligible. After then, the current mirror 234 repeats the amount of the bit line current, where the current value can be controlled by the channel width, length, and multiple mirrors. By the current mirror, the pre-charged node 236 is discharged from pre-charged voltage to ground, where the latch node 236 is pre-charged by the PMOS 235 when pre-charge bar (PB) signal is at ground level during standby. After pre-charging, PB signal is de-asserted before the word line is asserted. Hence, the voltage output (VO) of the inverter 237 is changed from VL level (ground level) to VH level (high level of the memory array), and transferred to next stage (not shown). After latching the stored data, feedback inverter 238 and inverter 237 keeps the stored data. Simultaneously, the switch 231 is turned off by the inverter 239 (at ground level), thus the data latch cuts off the current path of the bit line after read data “1”, in order to reduce the active current.

After transferring voltage output VO, the word line 201 is de-asserted to VL level to finish the read cycle. By lowering the word line 201 to VL level, the collector 204 of p-n-p Q1 (also the base 204 of n-p-n Q2) is discharged by the word line 201, but the word line can not fully discharge the collector 204 because p-n-p Q1 is turned off when the collector 204 is reached around built-in voltage VFP. The remained charges are swept by the forward bias (from p-type region 204) to n-type region 205 because the word line does not provide positive charges after de-asserted to VL level and the forward bias leakage current sweeps the remained positive charges. As a result, the diode access device can fully cut off the current path during standby or unselected after the word line is de-asserted to VL level. In doing so, the unselected cell does not generate any interference or noise when read and write data. Furthermore, the read operation is nondestructive because the storage node 203 is not changed after read.

In order to read data “0”, the word line 201 is asserted but p-n-p Q1 is not turned on because the storage node 203 is reverse-biased from the word line 201 when the storage node voltage is higher than the word line voltage. Hence, read data “0” is quite different from read data “1”. Neither the forward bias is established nor the current path be set up. In doing so, p-n-p Q1 and n-p-n Q2 are turned off. The storage node voltage is not changed, and the bit line voltage is not changed either. And the pre-charged node 236 is not changed because the current mirror 234 does not flow any current. Hence, output VO keeps VL level. Neither the latch device require the reference voltage nor wait long discharging time of the bit line with strong diode current, while the conventional comparator type sense amplifier requires the reference voltage to compare, and waits the bit line to be discharged enough voltage because the MOS transistor is very slow with shallow inversion layer.

Alternatively, the storage capacitor 207 has two plates as a storage element. A series capacitor can be used as s storage element, which contains three plates, wherein the floating plate in the middle of the capacitor does not contain any data. Also the capacitor has leakage current which is negligible. Thus the floating node is in the range between the plate line voltage and ground, which means that the floating plate is not charged too high or too low voltage. In doing so, there is no over-stress with the floating plate. In FIG. 2B, the series capacitor is illustrated, wherein a series capacitor 257 works as single capacitor 277 equivalently. There is an advantage to use series capacitor as a storage element, such that one of the capacitor is broken and shorted, but the memory gains more capacitance and it still works well with more capacitance, which realizes high reliability in the critical applications, and increases memory yield. Furthermore, the capacitor material can be ordinary dielectric capacitor and ferroelectric capacitor, in order to retain the charges during pre-determined period. Refresh operations are performed before the stored charges are lost by the leakage current to the adjacent nodes, wherein the refresh operation is to read the stored data from the memory cell and write back the data to the memory cell. The write operation will be explained as below.

Referring now to FIG. 3A in view of FIG. 2A, a timing diagram is illustrated when the word line is asserted, where the plate line 358 is constant voltage to couple the capacitor, within the range between VH level to VL level. The insulator has less stress where the plate line is around middle of the VH level as the conventional DRAM, such as VH/2. By raising the word line 351, the current path 356 (I_{ON}) is set up, wherein the stored data is “1” during read cycle. Otherwise, there is no current flow (I_{OFF}) as shown 356′ when the stored data is “0”. And in FIG. 3B, I-V curve of the memory cell is depicted. When reading data “1”, I_{ON} current flows during read cycle. Thus, the word line voltage (VWL) is determined by three elements, such as the gate voltage (VGS) of pull-down NMOS device (233 in FIG. 2A), the collector-emitter voltage (VCE) of n-p-n Q2 in FIG. 2A and the base-emitter voltage (VBE) of p-n-p Q1 in FIG. 2A. Once the diode is turned on when reading data “1”, the current path is sustained by the feedback loop, which also sustains the word line voltage (VWL). On the contrary, when reading data “0”, the diode does not flow any current, except I_{OFF} current (reverse bias leakage). And during standby, the word line is de-asserted to ground level by the row decoder (not shown), which does not flow any current.

In FIG. 3C, I-V curve of conventional bipolar transistor is illustrated as a reference. The bipolar transistor's usefulness may be terminated as the collector voltage is increased, which is called “punch-through” or “reach-through” as described in the reference, “Microelectronics: Digital and Analog Circuits and Systems”, pp. 83, Jacob Millman, Ph. D. 1979 MacGraw-Hill, Inc. ISBN 0-07-042327-X, where punch-through is occurred when the base-collector voltage reaches a certain (device specific) value, the base-collector depletion region boundary meets the base-emitter depletion region boundary. When in this state the transistor effectively has no base. The device thus loses all gain when in this state. Thus, punch-through should be avoided having enough base area, or reducing the collector-emitter voltage. In the present invention, punch-through is simply avoided by selecting wide base region or reducing the collector-emitter voltage.

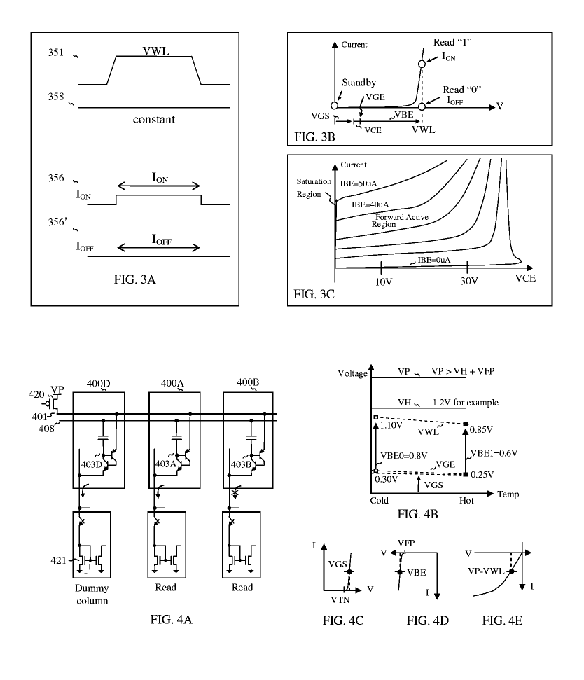

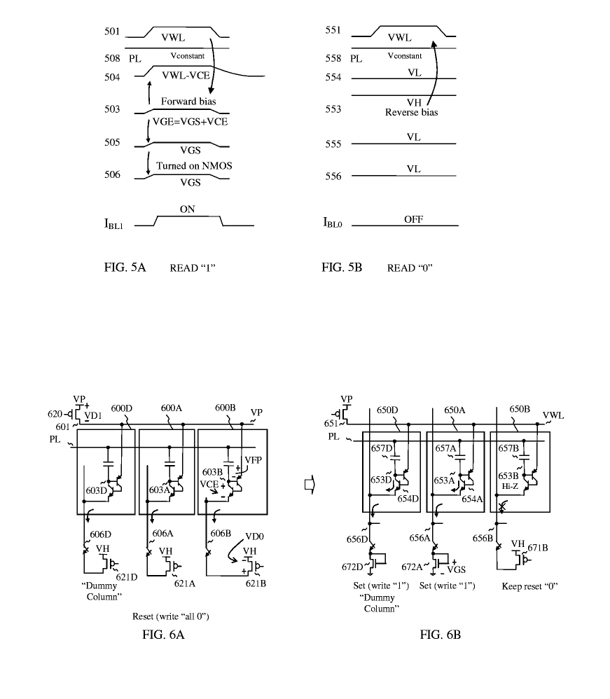

In FIG. 4A, more detailed read path is illustrated as the present invention. In the memory array, multiple memory cells are connected to the word line 401 and a plate line 408, such that the memory cell 400A stores data “1” in the storage node 403A, the memory cell 400B stores data “0” in the storage node 403B, and dummy cell 400D stores data “1” in the storage node 403D. When read, at least one memory cell is tuned on, in order to sustain almost same voltage of the word line regardless of the data pattern. In doing so, single or multiple dummy cells are added to limit the word line voltage under VH level, as explained in FIG. 3B. Without dummy cell, the word line voltage can be reached to VP level through pull-up PMOS 420 which is part of word line driver, when all the stored data are “0” because all the memory cells are turned off. At the same time, all the memory cells are corrupted by the forward bias, because the storage node is at VH level, where VP level is determined for write operation, not read operation. VP level is determined higher than the sum of VH level plus VFP level (built-in voltage of p-n-p Q1), which will be explained as below in FIG. 6A and 6B. In order to avoid all “0” corruption, the word line voltage is sustained lower than VH level by turning on at least a dummy cell, and the current flows through the pull-down NMOS 421.

Thus, the word line voltage is determined (as VWL in FIG. 4B), such that the word line voltage is the sum of three elements, such as VGS (the gate voltage of pull-down NMOS 233 in FIG. 2A), VCE (the collector-emitter voltage of n-p-n Q2 in FIG. 2A), and VBE (the base-emitter voltage of p-n-p Q1 in FIG. 2A), where VGS is 0.25˜0.3V range in recent MOS transistor, VCE is lower than 0.1 v which is ignorable with strong bipolar gain, and VBE is 0.6˜0.8V for silicon, for example. In addition, the voltages depend on the ratio among the resistances of three elements. Moreover, the word line voltage depends on temperature, because threshold voltage of MOS transistor and built-in voltage of p-n-p transistor are decreased as temperature is increasing. As shown example in FIG. 4B, the word line voltage VWL is 1.1V at 0° C. As temperature is increasing, the word line voltage is decreased to 0.85V at 100° C. More detailed current-voltage curves are illustrated in FIG. 4C, 4D and 4E. The I-V curve of pull-down NMOS transistor is shown in FIG. 4C, wherein the threshold voltage of NMOS transistor is VTN, and the applied voltage of the transistor is VGS, where VGS level is determined by the current flow including pull-down NMOS, p-n-p-n diode and pull-up PMOS. Thus, VGS level is at least higher than VTN level when the diode is fully turned on and in latching state with the feedback loop, but VGS level is only slightly changed when the current is changed more because the curve is very steep above the threshold voltage of NMOS transistor. The I-V curve of base-emitter of p-n-p Q1 is shown in FIG. 4D, wherein built-in voltage (or threshold voltage) of p-n-p Q1 transistor is VFP, and the applied voltage of the transistor is VBE, where VBE level is determined by the current flow including pull-down NMOS transistor, p-n-p-n diode and pull-up PMOS transistor. Thus, VBE level is at least higher than VFP level, but VBE level is only slightly changed when the current is changed more because the curve is very steep above the built-in voltage of p-n-p Q1 transistor. In FIG. 4E, I-V curve of pull-up PMOS 420 is shown, wherein the applied voltage of pull-up PMOS is determined by subtracting the word line voltage VWL from VP level of supply voltage, which curve is less steep, thus the applied voltage of pull-up PMOS is varied by the word line voltage. The applied voltage of pull-up PMOS is VP-VWL as shown in FIG. 4E.

The bit line voltage is near VGS level if the bit line resistance is ignorable, and the collector-emitter voltage VCE of n-p-n Q2 is relatively low because collector current is much higher that base current when the bipolar transistor is turned on in nature. Hence, VCE level is lower, which is ignorable. In this respect, the storage node voltage (VGE) is very close to VGS level, when the stored data is “1”, where VGE=VGS+VCE, and VGE=VWL−VBE as shown in FIG. 4B.

By asserting the word line 401, the memory cell 400A and 400D are turned on because the forward bias is set up from the word line 401 to the storage nodes, where the storage node 403A and 403D are lower than VWL level. After the storage node was written at VGE level, its charges are leaked by the reverse bias leakage through the emitter which is connected to the word line 401 at VL level during standby, which helps to read data “1” by establishing the stronger forward bias for the next read cycle.

When the stored data is “0”, there is no current path, such that the memory cell 400B is not turned on because the storage node voltage is higher than word line level (VWL), which results in reverse bias. With no current consumption when read “0”, power consumption is reduced if the memory cell stores data “0”. When all the memory cells store data “0”, only dummy cells are turned on, in order to avoid the corruption by the forward bias. Turning on dummy cells, the word line voltage is limited lower than VH level as explained above, at VWL level.

Referring now to FIG. 5A in view of FIG. 2A, timing diagram for read “1” operation is illustrated. In order to start read cycle, the word line 501 is asserted, where the plate line (PL) 508 keeps constant voltage. Thus, the word line voltage is reached to VWL level. When the stored data is “1”, the storage node 503 is around VGE level during standby. Thus the forward bias is established by asserting the word line 501. And then, the base 504 of n-p-n Q2 in FIG. 2A (also collector 504 of p-n-p Q1 in FIG. 2A) is raised by turning on p-n-p Q1 in FIG. 2A. At the same time, n-p-n Q2 is turned on, which raises the emitter 505 and the bit line 506. When the bit line 506 is reached to threshold voltage (VTN) of NMOS, pull-down NMOS is turned on. The bit line current I_{BL1} is appeared during the word line is asserted.

Referring now to FIG. 5B in view of FIG. 2A, timing diagram for read “0” operation is illustrated. The word line 551 is asserted to start read cycle, where the plate line (PL) 558 keeps constant voltage. Unlike read “1”, when the word line 551 is raised, the forward bias is not established between the storage node 553 and the word line 551, because the storage node 553 is near VH level. Hence, reverse bias is set up. As a result, there is no current path (I_{BL0}). Read “0” does not consume current from the word line 551 to the bit line 556, which helps to save active power. After read data “1” and“0”, the voltage of capacitor storage is not changed, thus read operation is nondestructive.

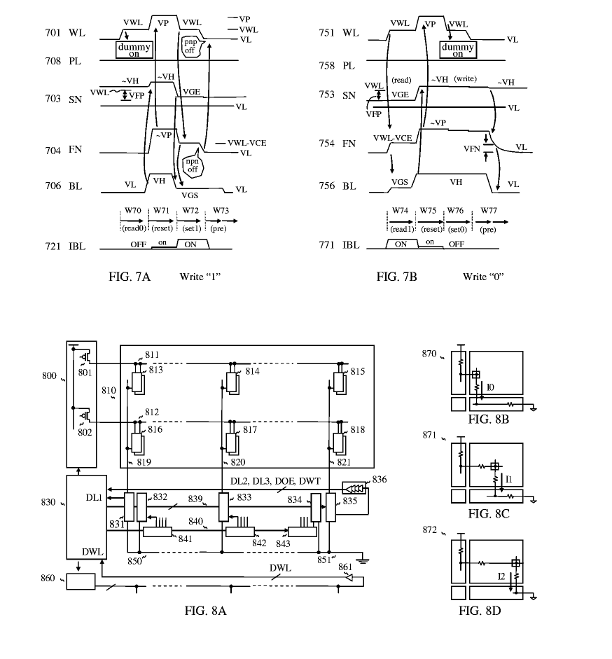

In FIG. 6A to 7B, write operation is illustrated. In order to write data, all the capacitor storages on a selected row are reset, and then set selectively, where reset operation is to write data “0” at a time, and set operation is to write data “1” or to sustain reset state “0” selectively. During reset operation, all the stored data are erased in a selected row. Hence it is called “erase”. This means that the stored data in the unselected columns should be moved to the data latch during reset, while the data of the selected columns will be modified by the external write data. After reset, the stored data in the data latches are moved to the memory cells. It is called “write back”. At the same time, the external write data are moved to the memory cells of the selected columns. This procedure is called “read-modify-write”, which is generally used to implement high density memory where the numbers of column in the array are more than those input and output from the external ports, in order to keep the stored data in the unselected columns during write operation.

In order to execute “read-modify-write” operation, read operation is firstly executed by asserting the word line 601 with the row decoder signal 620. Thus the stored data are read from the memory cells, and stored to the latches (which will be explained as below). When read, the applied voltage of the word line is determined regardless of the supply voltage of the row decoder as explained above. However, when write, the applied voltage of the word line is reached to the supply voltage, during reset operation.

As shown in FIG. 6A and 6B, the supply voltage of the word line is VP level. During reset operation, the applied voltage of the bit line is fully transferred to the storage node, because the supply voltage of the word line is VP level which is higher than the sum of VH level and VFP (built-in voltage of p-n-p Q1) in order to reduce voltage drop of the storage node when the bit line drives VH level. All the bit lines 606A and 606B including the dummy column 606D are raised to VH level, the voltage of the word line 601 is raised to VH+VFP level, and forward bias is set up for all the cells. By the forward bias, p-n-p transistors are turned on, and then n-p-n transistor is turned on by turning on p-n-p transistor, thus the current path is set up. When the current path is set up from the word line 601 to the bit line, VH level is lowest voltage in the current path. As a result, the storage node 603A, 603B and 603D are raised around VH level. The relations are shown in FIG. 6A, such that the voltage of the bit line 606B is VD0 level (applied voltage of PMOS 621B) plus VH level, where PMOS 621B is fully turned on to raise the bit line to VH level. And the storage node voltage 603B is the sum of VCE level (collector-emitter voltage of n-p-n Q2), VD0 level (applied voltage of PMOS 621B) and VH level. Thus, all the bit lines 606A, 606B and 606D are raised by the pull-up PMOS 621A, 621B and 621D respectively, in order to reset “0”. In this manner, reset “0” operation is completed, such that all the storage nodes are reset around VH level, as shown in FIG. 6A. The reset operation is a preparation for set operation as below.

In FIG. 6B, set operation is illustrated as the present invention. After reset “0” operation, set operation is executed in order to write data “1” but the write data “0” operation is to keep the reset “0” state, wherein the bit lines 656A and 656D are forced to VGS level by turning on pull-down NMOS 672A and 672D, in order to set “1” for the selected cell 650A and 650D. By lowering the bit lines, the current paths are set up from the word line 651 to the selected bit lines 656A and 656D because the base of n-p-n transistor 654A and 654D (also collector of p-n-p transistor) are already reached around VP level during reset operation. Thus, the selected storage nodes 653A and 653D are pulled down by the current paths. When the storage nodes are reached to VGE level (near the bit line voltage), the current path is in steady state, where the amount of the current is the same as read cycle as explained above. In this manner, the storage nodes 657A and 657D are set to VGE level.

While the memory cells 650A and 650D are set to data “1”, the memory cell 650B keeps the reset “0” state, wherein the bit line 656B keeps VH level with pull-up PMOS 67 1B. Sustaining the bit line 656B to VH level, the storage node 653B is floating with no current path. This means that the storage 657B is not changed. After then, the word line 651 is de-asserted to VL in order to complete the write cycle. The word line pulls down the floating node 654B but it can not fully discharge the floating node because p-n-p transistor is turned off at built-in voltage VFP of p-n-p transistor. And the remained charges are swept by the bit line 656B when it is de-asserted to ground level after the word line is fully reached to ground level.

Referring now to FIG. 7A in view of FIG. 6A and 6B, timing diagram is illustrated for the write “1” operation, as the present invention. In order to execute “read-modify-write” operation, the word line 701 is asserted firstly during write sequence W70, but the memory cell is not turned on because the storage node 703 stores near VH level, which establishes reverse bias, when the voltage of the word line 701 is reached to VWL level by turning on the dummy columns, as explained above in FIG. 6A and 6B. In doing so, read “0” operation is performed. During read, the plate line 708 is connected to a constant voltage source to couple the capacitor.

After reading data “0”, the bit line 706 is raised to VH level to reset. By raising the bit line, the word line 701 is raised because the current path is cut off by turning off the dummy columns. When the word line is reached to built-in voltage of p-n-p transistor, the forward bias is established from the word line 701 to the storage node 703 as shown in write sequence W71, which turns on p-n-p transistor and pulls up the floating node 704 (collector of p-n-p transistor) up to VP level. In doing so, n-p-n transistor is turned on by pulling up the floating node (also base of n-p-n transistor). Thus the current path is set up from the word line 701 to the bit line 706. After then, the storage node 703 is raised around VH level by the current path because the word line pulls up the storage node. In this manner, reset operation is to establish the storage node 703 around VH level. And then, set “1” operation is performed to write data “1”, by asserting the bit line to VGS level, thus n-p-n transistor is turned on because the base 704 (floating node 704) is already reached near VP level during reset, as shown in write sequence W72. Also p-n-p transistor is turned on because the base 703 (storage node 703) is lowered by turning on n-p-n transistor. Thus the current path is set up from the word line 701 to the bit line 706. As a result, the storage node voltage is sustained at VGE level. After then, the word line 701 is de-asserted to ground level to complete write operation. By lowering the word line, p-n-p transistor and n-p-n transistor is turned off. After the word line is lowered, the bit line is pre-charged to ground level for the next cycle, as shown in write sequence W73, where the bit line current (IBL) 721 is shown.

Referring now to FIG. 7B in view of FIG. 6A and 6B, detailed timing diagram is illustrated for the write “0” operation, as the present invention. In order to execute “read-modify-write” operation, the word line 751 is asserted firstly during write sequence W74, where the plate line 758 is connected to a constant voltage source to couple the capacitor. Thus the memory cell is turned on because the storage node 753 stores near VGE level, which establishes forward bias, when the voltage of the word line 751 is reached to VWL level. In consequence, the current path is set up from the word line 751 to the bit line 756, which raises the bit line to VGS level. After then, reset operation is executed by raising the bit line 756, as shown in write sequence W75. During reset operation, the floating node 754 is reached near VP level as explained in FIG. 7A, which enables to turn on n-p-n transistor. Hence the bit line forces VH level to the storage node 753. After reset, set operation is performed as shown in write sequence W76, but set “0” operation is to sustain reset state because the storage node 753 is already raised to VH level during reset operation. And during set operation, the word line is lowered to VWL level by turning on the dummy columns, in order to avoid discharging the storage node, as explained above. After then, the word line 751 is de-asserted to VL level in order to pre-charge nodes for the next cycle, as shown in write sequence W77. While the word line is lowering, there is almost no charge loss in the storage node because the word line is quickly reverse biased. But there is very slight charge loss in the storage node during the transition time of the bit line, which is negligible, because n-p-n transistor is very quickly turned off by the forward bias to the bit line (at ground level).

In the configuration of the circuits as shown in FIG. 6A and 6B, the supply voltage of the word line is VP level, which is higher than the sum of built-in voltage of p-n-p transistor and supply voltage of the bit line, in order to reset the storage node to VH level when the bit line is asserted to VH level. This configuration has advantages with no change of the plate line when write. Thus, there is no need of decoder for the plate line, which realizes fast operation and reduces power consumption because the plate line is heavily loaded with all the capacitors. The drawback is to use VP level for the word line, which can be generated by the internal pumping circuit (not shown), or external power supply.

In the present invention, one of advantages to use diode access device is that the diode access device is not sensitive to capacitance variation in order to store data. This means that the storage capacitor only contributes to set up the initial condition of storage node when read, while the prior art of capacitor memory is very sensitive with the capacitance value because the stored charges are redistributed with the heavily loaded bit line through MOS access transistor. In the present invention, there is no need of high capacitance to read. Furthermore, in the present invention, the diode also serves as a sense amplifier to detect the initial voltage of the storage node whether it is forward bias or not, when the word line is asserted to read. After detecting the forward bias, the diode is turned on, which sets up the current path to the bit line. In doing so, in the present invention the memory yield will be increased by reducing the sensitivity of the capacitance variations. Moreover, access time is fast because the diode current is much higher than that of MOS access transistor.

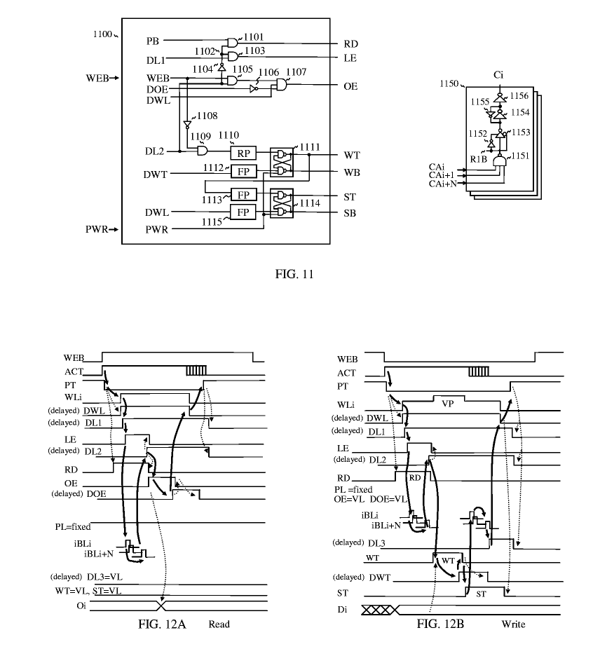

In FIG. 8A, an example array configuration using the invented capacitor memory is illustrated, wherein the word line driver 800 is connected to the memory cell array 810, the word line driver 800 is controlled by the control block 830, the control block 830 is also connected to read-write circuits 831, 832, 833, 834 and 835, read-write circuits are selected by the column decoders 840, 841 and 842, and a dummy word line driver 860 is controlled by the control block 830. Unlike MOS access device, the diode access device faces serious data pattern sensitivity when multiple memory cells are connected to a word line. For example, when all the stored data are “1”, all the memory cells on the word line are turned on, which causes severe voltage drop. Single word line may not provide enough current for all the memory cells, when the segmented memory array is big for the high density memory configuration. This means that the diode-based capacitor memory needs more row decoders and more segmentation than those of the conventional MOS transistor-based memory, in order to avoid the data pattern sensitivity. Alternatively, a circuit technique is introduced to reduce the number of row decoder for the diode-based capacitor memory. Thus, single row decoder drives many memory cells with sequential switching, such that “self-closing data latch” is used, wherein the current mirror repeats the amount of current that the memory cell flows when the stored data is “1”, and after latching data “1”, the current path is self-closed by the latch output, while the stored data “0” does not flow current and it does not affect the voltage drop. At a certain time period, the limited numbers of memory cell are turned on by using self-closing data latch, and it depends on various conditions, such as process, voltage, temperature, layout and array size. For example, 5 memory cells are turned on at high voltage and fast process. After 5 memory cells in the near side of the word line driver are turned on, those memory cells are self-closed, and then next 5 cells are turned on because the word line voltage is raised after near side 5 cells are turned off. At this time, the voltage of far side the word line is lower than that of near side because the word line starts to rise from the near side. In contrast, at low voltage and slow process, 10 memory cells are turned on, for example, because the feedback loop is slow. As shown in FIG. 8A, read-write circuits 831, 832, 833, 834 and 835 include self-closing data latch, which will be explained in FIG. 11.

In addition, total resistance of the current path is equally distributed regardless of the location of the memory cell in physical connection. As shown in FIG. 8A, when the word line 811 is selected by the pull-up PMOS 801, the memory cells 813, 814 and 815 are activated. The current path for each memory cell is equal in resistance where the ground line 850 and 851 are reversely distributed toward the word line 811. When the word line 812 is selected by the pull-up PMOS 802, the memory cells 816, 817 and 818 are activated with equal in resistance as the word line 811. In this manner, total resistance for each cell is equal or similar. The examples are illustrated, such that when the near side memory cell is turned on, the current path 10 in 870 (in FIG. 8B) is set up, when the middle of memory cell is turned on, the current path I1 in 871 (in FIG. 8C) is set up, when the far side memory cell is turned on, the current path I2 in 872 (in FIG. 8D) is set up. And those current paths include multiple memory cells.

The column decoders 840, 841 and 842 (in FIG. 8A) select columns to read and write, which column decoders are controlled by the control block 830. In order to control the memory array more efficiently, replica delay circuits are introduced, wherein the near side dummy column includes the dummy cells 813 and 816, and read-write circuit 831, the far side dummy column includes the dummy cells 815 and 818, and read-write circuit 835. A delayed signal DL1 is generated by the near side dummy column and three delayed signals DL2, DL3 and DL4 are generated by the far side dummy columns, and those signals are returned by the buffer block 836. Alternatively, multiple dummy columns can be added to replace the failed dummy column with non-failed dummy column (not shown), as the repair scheme is conventionally used in the memory array. And there is one more replica delay circuit 860 for generating delayed signal to track the word line, which is the dummy word line DWL, and which signal is returned by the buffer 861. The related operations will be explained in FIG. 9, 10, 11 and 12.

In FIG. 9, read-write circuit 910 and memory cell 904 are illustrated as the present invention, in order to explain read and write operation. The read operation is related to “pre-charge” and “read”, such that the pre-charge state is sustained while pre-charge true (PT) signal is at VH level and pre-charge bar (PB) signal is at VL level. After then, PT signal is lowered to VL level and PB signal is raised to VH level, in order to read data. Hence, pull-down NMOS 911, 914 and 940 are turned off, and pull-up PMOS 919 and 946 are turned off. The starting of read operation is to assert the word line 901. By raising the word line 901, the forward bias is established between the word line 901 and the storage node 905 when the stored data is “1”. By the forward bias, p-n-p transistor is turned on and the floating node 906 is raised by turning on p-n-p transistor around the word line level. By raising the floating node 906, n-p-n transistor is turned on. Thus, the current path is set up from the word line 901 to the bit line 907. After the current path is set up, the voltage of the word line 901 is at a steady state VWL level as explained above. And then, the current flow gradually raises the gate of pull-down NMOS 916, while the NMOS switch 912 and 913 are turned on during read. When the gate of pull-down NMOS 916 is reached to the threshold voltage, pull-down NMOS 916 is turned on. Simultaneously, the current mirror 917 is turned on, which repeats the current that the memory cell flows, but the pull-up of inverter 922 resists to change the latch node 920 from the pre-charged VH level to VL level, when NMOS 918 is turned on by latch enable LE signal (at VH level). In order to flip the latch node 920 to VL level, the strength of the current mirror 917 is much stronger than that of inverter 922. In this manner, the potential of latch node 920 is changed from VH level to VL level. After then, the result is transferred to node 925 through inverters 921 and 924, and also inverter output 923 (becomes DL1 or DL2 signal) is changed to VH level. After then, latched output 925 is transferred to output data bus Oi, when output enable OE signal is asserted to VH level, and column decoder output Ci is asserted to VH level. Hence, clocked inverter 931 is enabled by AND gate 929 (at VH level) and inverter 930 (at VL level). In contrast, when the stored data is “0”, the forward bias is not established. Thus, the latch node 920 is not changed. And output Oi is at VL level. During read operation, all the write signals are not asserted. In the read operation, the threshold voltage of the current mirror 916 and 917 is sensitive to turn on the current mirror. Hence, low threshold transistor can be used as the current mirror in order to achieve fast read, alternatively.

When starting the read operation, coupling noise affects the floating bit line which is connected to the cell that stores data “0”, thus the floating bit line is coupled by the adjacent bit lines. In order to suppress coupling noise when reading, there are 3 features to reject or reduce the coupling noise. First feature is that the ratio between the feedback inverter 922 and the current mirror 917 can be adjusted, such that the bit line is coupled by the adjacent bit lines which stores data “1”, but the latch node 920 is not flipped because the feedback inverter 922 will reject the change with coupling-based weak current. In order to reject the coupling noise, the ratio between the pull-up device of the inverter 922 and the current mirror 917 including NMOS 918 should be optimized depending the conditions, such as process, operating voltage, layout and so on. Second feature is that the MOS gate capacitor 915 is used as a noise filter, such that the gate of current mirror 917 is slowly changed by the capacitor. In doing so, the coupling noise will be reduced. The capacitance value is not bigger than parasitic capacitance of the bit line. Third feature to suppress coupling noise is that the latch enable (LE) signal is turned on after the nearest dummy column is turned on, which enables to measure the current mirror after the bit line is stable, while LE signal of the dummy column is always fixed at VH level to detect the completion of the current path.

Before writing data to the memory cell 904, the stored data is read from the memory cell as the read operation. This is required to configure very high density memory because only selected columns are modified while unselected columns are not modified. The read data from the unselected columns are temporarily stored in the data latch during reset, and then the data are written back to the memory cells. The plate line 902 is connected to a constant voltage source to couple the storage capacitor when read and write. In order to reset, the dummy columns are turned off, and all the bit line are raised to VH level. Thus, the word line is raised nears VP level, and the forward bias is established from the word line to the bit line. As a result, all the memory cells are turned on regardless of the previous data, and the reset operation is completed.

While reset “0” operation is executed by the bit line 907 with WB signal, the latch node 945 is pre-charged to VH level by the PMOS 947, when the WB signal is at VL level. At the same time, the NMOS 941 is turned on by the WT signal, and it lowers the node 939, in order to turn off the current mirror 943. One more preparation is required to prepare the set operation, which is to receive external write data to the latch node 920 from write data bus Di. When WT signal is asserted to VH level and column decoder output Ci is selected to VH level, clocked inverter 926 is enabled by the AND gate 928 (at VH level) and inverter 927 (at VL level). In doing so, external data Di is stored to the latch node 920. At this time, OE signal keeps VL level during write operation. And other signals are also de-asserted, such that PT, RD, LE, A1, ST signal are at VL level, PB, SB signal are at VH level.

After the preparations are completed, the set operation is executed by asserting ST (set) signal to VH level and SB (set bar) signal to VL level. When the inverted latch node 923 stores data “1” (VH level) and the latch node 920 keeps VL level which are set up by WT signal previously, the bit line 907 is lowered by the pull-down NMOS 942, because the current path is set up by turning on NMOS 935 with ST signal and NMOS 934 (at VH level) with inverted latch node 923. And NMOS 938 is already turned on by the preparation with WB signal. When the node 939 is reached to the threshold voltage of NMOS transistor, NMOS 942 is turned on. At this time, the storage node 905 is reached to VGE level by the pull-down NMOS 942. As a result, the storage node 905 is lowered to VGE level. While the storage node is charged to VGE level (near the bit line voltage), the current mirror 943 is turned on and it pulls down the latch node 945 to VL level through NMOS 944. After then, the voltage of the latch node 945 is transferred to feedback node 952 through the inverter 948 and 950. By the feedback node 952, the NNOS switch 938 is cut off, after writing data “1”. In this manner, set “1” operation is to charge the storage node to near the bit line voltage, which enables the memory cell to store data “1”.

In contrast, set “0” operation is to keep the reset state, such that when the inverted latch node 923 stores data “0” at VL level, and pull-up PMOS 937 is turned on, while NMOS 934 is turned off. Hence, the bit line 907 keeps VH level when PMOS 936 is turned on by SB signal at VL level and PMOS 937 is turned on by the inverted latch data 923. Thus the storage node 905 is floating when the bit line keeps VH level because the word line at VWL level cuts off the current path by p-n-p transistor, such that the base of n-p-n transistor is lower than VH level. The storage node 905 is remained on the reset state which is data “0”. In doing so, set “0” operation is to keep the reset “0” state. After then, the word line is de-asserted to VL level, and then the bit line 907 is also de-asserted to VL level to complete write cycle.

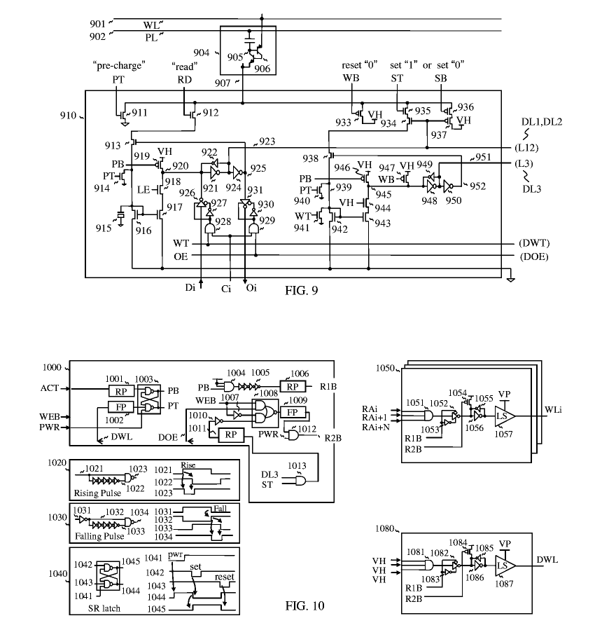

In FIG. 10, row control circuit and row decoder circuit are illustrated in order to remove timing race conditions such that all the control signals are consecutively generated after an operation is completed. The row control circuit 1000 generates pre-charge true (PT) control signal and pre-charge bar (PB) signal, which control circuit 1000 includes 3 sub-circuits, such that the sub-circuit 1001 detects rising edge of external active signal (ACT), the sub-circuit 1002 detects falling edge of the dummy word line (DWL) signal, and the sub-circuit 1003 which is called SR (set-reset) latch, generates PT signal. And the row control circuit 1000 also generates row decoder enable signals R1B and R2B. The word line driver (row decoder) 1050 generates the word line WLi and the dummy word line driver 1080 generates the dummy word line signal DWL. In the row control circuit 1000, external control signals are asserted, such that power on (PWR) signal initializes SR-latch 1003, active signal (ACT) activates the whole memory circuit to read or write, write enable bar (WEB) signal enables to write when it is asserted to VL level, otherwise read operation is executed, and row address RAi, RAi+1 and RAi+N signals are decoded to select one of the rows.

In order to read data from the memory cell, ACT signal is asserted to VH level, and WEB signal keeps VH level, simultaneously row and column addresses are asserted to select one row and one column (or multiple columns) before asserting ACT signal. By asserting ACT signal, PB signal is raised to VH level by the rising pulse generator 1020, wherein the rising edge generator receives an input 1021, and the inverted output 1022 is generated by the inverter chain, thus NAND gate 1023 generates a pulse from the rising edge of the input 1021. After setting PB signal, the whole memory array is activated. After then, the delayed signal DWL from the dummy word line changes the state of the PT signal from VL level to VH level, also PB signal is changed to VL level, in order to finish active cycle, wherein the dummy word line is driven by the dummy row decoder 1080. Using the dummy word line, a replica delay signal is obtained, which includes all the parasitic resistance and capacitance in order to simulate the main word line delay. And the delayed signal DWL is returned from the end of the word line. Thus the returning delay would be margin for resetting PT and PB signal. During falling edge of DWL signal, the falling pulse generator 1002 generates a pulse, which resets SR-latch 1003. In doing so, PT and PB signal are initialized to reset state, wherein the detailed falling pulse generator is illustrated in 1030, such that while the input 1031 is falling, the inverter generates an inverted signal 1032 and inverter chain output 1033 is delayed and inverted from the inverted signal 1032, thus NAND gate 1034 generates a pulse from the falling edge of the input 1031. And the detailed SR-latch is illustrated as shown 1040, while the initializing signal 1041 is at VL level, the reset output 1044 is raised to VH level by the NAND gate, and the set output 1045 is set to VL level because the input 1042, 1043 and 1044 are at VH level, NAND gate output 1045 generates VL level, after resetting output 1044 (at VH level) and 1045 (at VL level), set signal 1042 receives a short low pulse from the pulse generator which sets the set node 1045 to VH level, because the low pulse raises the set output 1045 to VH level, simultaneously the reset output 1044 is lowered to VL level which stores the state after the low pulse is disappeared. Similarly, reset operation is performed by asserting the low pulse to the input 1043 (at VL level), which raises the reset output 1044 to VH level, at the same time the set output 1045 is lowered to VL level.

Now the operation of row decoder is explained to select one of the word lines. After ACT signal raises PB signal to VH level and lowers PT signal to VL level, PB signal drives 3-input NAND gate 1004, which generates an active low pulse R1B with rising pulse generator 1005, where 3-input AND gate 1004 has same delay as the AND gate 1051 of the row decoder 1050, and the delay chain 1005 delays the output of AND gate 1004 to add timing margin for enabling the row decoder 1050. Then R1B signal enables clocked inverter 1052 with inverter 1053, in order to latch the row decoder output from 3-input AND gate 1051. When the clocked inverter 1052 is enabled, one of the word lines WLi is raised to VP level, such that when the output of AND gate 1051 is at VH level, and the output of clocked inverter 1052 is lowered, which raises the output of inverter 1056 to VH level, and the word line WLi is raised by the level shifter 1057. The level shifter shifts VH level to VP level, which level shifter is conventionally used in the semiconductor chip, thus the operation and circuit of the level shifter are not explained in the present invention. While row decoder 1050 selects WLi signal, dummy row decoder 1080 selects dummy word line DWL, such that R1B signal enables clocked inverter 1082 with inverter 1083, in order to latch VH level from 3-input NAND gate 1081. When the clocked inverter 1082 is enabled, the dummy word line DWL is raised to VP level, such that when the output of AND gate 1081 is at VH level, the output of clocked inverter 1082 is lowered, which raises the output of inverter 1086 to VH level, and the dummy word line DWL is raised by the level shifter 1087 as the row decoder works.

While the word line WLi and the dummy word line DWL are raised by the falling pulse of the R1B signal, WLi and DWL signals are reset by R2B signal, such that pulse generator 1009 generates an active low pulse when the output of AOI (And-Or-Inverter) 1008 is falling. There are two cases to generate R2B pulse. During read cycle, WEB signal is at VH level and DOE signal is asserted to VH level, where DOE signal is asserted to VH level after output is transferred to output bus, which signal will be explained in FIG. 11. During write cycle, WEB signal is asserted to VL level. Thus, the output of inverter 1007 is raised to VH level, and the output of inverter 1010 is also raised to VH level by the rising edge pulse generator 1011 when DL3 is raised and ST signal is at VH level. As a result, R2B signal generates an active low pulse when the output of AOI (and-or-inverter) 1008 is lowered to VL level, in order to reset WLi and DWL signal.

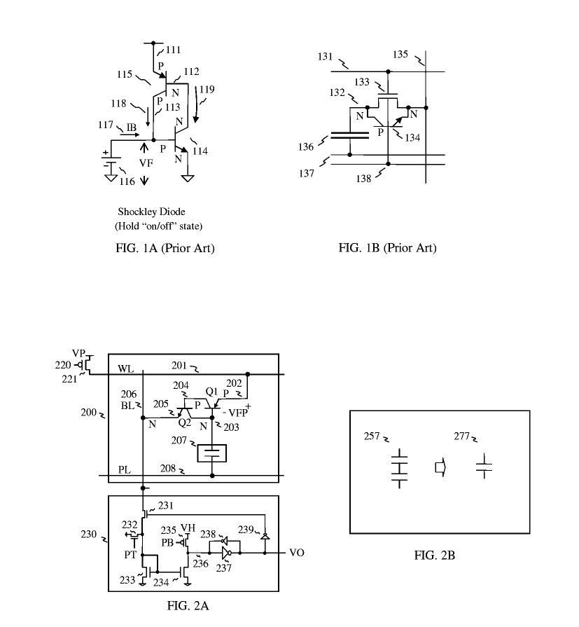

Referring now to FIG. 11 in view of FIG. 8, 9 and 10, column control circuit 1100 and column decoder 1150 are illustrated, wherein the column control circuit 1100 generates many control signals in order to read and write the memory cell, and column decoder 1150 generates column decoder output Ci when R1B signal is lowered, wherein NAND gate 1151 is selected to VL level, the clocked inverter 1153 is raised to VH level, the latch 1154 and 1155 stores the selected column address, and driver 1156 drives Ci signal. In order to read data from the memory cell, read enable (RD) signal is generated by the NAND gate 1101 when PB signal is asserted to VH level and DL2 signals is at VL level. During this period, the word line and dummy word line are asserted. By asserting the word line, the nearest dummy column sets up the current path because the dummy cells always store data “1”. When the current path is established, the latch node (920 in FIG. 9) is lowered to VL level by the current mirror (917 in FIG. 9), thus the latch node voltage is transferred to node 923 and generates L12 signal in FIG. 9. And L12 signal of the near side dummy column becomes DL1 signal in FIG. I1. And the read data latches wait until the near side dummy column sets up the current path and generates latch enable (LE) signal because the current mirror of dummy columns are already enabled, such that NMOS switch (918 in FIG. 9) is always turned on by connecting to VH level. When LE signal is asserted to VH level, all the current mirrors are enabled to measure the current from the memory cell. By raising LE signal, the memory cells that store data “1” are turned on, while the memory cells that store data “0” are not turned on. After then, the farthest dummy cell is turned on which also stores data “1”, thus the farthest dummy column generates L12 signal in FIG. 9 to VH level, and L12 signal is buffered and transferred to the column control circuit 1100 in FIG. 1, which L12 signal becomes DL2 signal. The role of DL2 signal is to detect whether the farthest dummy column establishes the current path, which means that the latch node 920 in FIG. 9 is flipped to VL level from pre-charged voltage VH level, and generates the output L12 in FIG. 9 to VH level. After DL2 signal is raised to VH level, read (RD) signal and latch enable (LE) signal are de-asserted to VL level by the signal 1102 which is inverted by DL2 signal. This means that the read latches are completed to store data from the memory cells.

After latching the stored data to the read data latches, output enable (OE) signal is raised to VH level by DL2 signal, in order to transfer the read data to the output data bus, such that clocked inverter (931 in FIG. 9) is turned on by OE signal. After then, OE signal is reached to the farthest dummy column, and it becomes DOE signal in FIG. 9. Thus DOE signal is buffered and returned to the column control circuit (1100 in FIG. 1). When DOE signal is raised to VH level, the output of inverter 1106 is lowered to VL level, thus OE signal is de-asserted to VL level. By lowering OE signal, DOE signal is lowered to VL level. And then, DOE signal disables the word line and dummy word line DWL as shown 1000 in FIG. 10, such that R2B signal generates an active low pulse when the output of AOI 1008 is lowered by the rising edge of DOE signal while WEB signal is at VH level. In doing so, R2B signal (active low pulse) turns on PMOS 1054 and 1084 in FIG. 10, thus, R2B signal resets the word line WLi by PMOS 1054 and dummy word line DWL by PMOS 1084. In doing so, the word line WLi and dummy word line DWL are lowered to VL level. After DWL signal is lowered, PB signal is lowered by DWL signal as shown in 1003 in FIG. 10. After then, PT (to VH level) signal and PB signal (to LV level) reset all the nodes to the pre-charge state, thus the whole read operation is completed.

Now write operation is explained, such that at the beginning of write cycle, read operation is performed as above, but output enable OE signal is not asserted. Instead of OE signal, write control signals are asserted because WEB signal is activated to VL level and WEB signal enables write control signals, such as WT, WB, ST and SB signal, while such signals are not asserted during read only cycle. More accurately, as shown in FIG. 11, WEB signal selects WT signal, and WT signal is raised to VH level by SR-latch 1111, in order to reset all the storage nodes to “0”, as follow. When DL2 signal (from farthest dummy column) is asserted to VH level, the output of AND gate 1109 is raised to VH level when inverter output 1108 is set to VH level by WEB (at VL level), thus the rising pulse generator 1110 generates an active low pulse after receiving the output from AND gate 1109. Hence SR-latch 1111 sets up WT signal to VH level. Simultaneously, WB signal is lowered to VL level. Hence WT signal enables the clocked inverter 926 in FIG. 9. In this manner, external data input Di is latched in the latch node (920 in FIG. 9) in order to write data to the memory cell in the next step which is set operation. PB signal and LE signal are previously disabled while latching external data.

After latching external data Di to the latch node, WT and WB signals are de-asserted by rising edge of DWT signal, because WT signal is delayed and generates DWT signal from the read-write circuit (910 in FIG. 9). After reset operation, ST signal is raised to VH level, and SB signal to VL level by SR-latch 1114, when WT signal is rising because falling edge detector 1113 generates an active low pulse to set SR-latch 1114. Hence, set operation is performed by ST and SB signal (as explained in FIG. 9).

After set operation, the farthest dummy column generates L3 signal (in FIG. 9), which is returned to column control circuit 1100 and becomes DL3 signal. When DL3 signal is rising, the word line WLi and the dummy word line DWL are de-activated to VL level. When DL3 signal is rising and ST signal is set to VH level from the previous operation, AND gate 1013 in FIG. 10 generates VH level and rising pulse generator 1011 in FIG. 10 receives the output and generates an active low pulse, which raises the output of inverter 1010 in FIG. 10 to VH level. Thus, AOI 1008 in FIG. 10 generates an active low pulse. Thus R2B signal is asserted to VL level by the falling pulse generator 1009 in FIG. 10. When R2B signal is lowered to VL level, row decoder 1050 in FIG. 10 and dummy row decoder 1080 in FIG. 10 de-assert WLi and DWL signal to VL level. When the dummy row DWL signal is falling, the ST and SB signal are reset SR-latch. At the same time, DWL signal resets SR-latch 1003 in FIG. 10. Thus, the whole write operation is completed.

In FIG. 12A, more detailed read operation is illustrated with timing diagram, which timing diagram helps to understand the transitions of the related signals, in order to read the stored data from the memory cell. During read cycle, WEB signal keeps VH level. And active (ACT) signal is asserted to VH level to activate all the read related signals, such that the rising edge of ACT signal changes pre-chare true (PT) signal to VL level. Thus, pre-charge state is finished. After then, the word line WLi and the dummy word line DWL are selected. And read (RD) signal is asserted to VH level. When the word line WLi is asserted, the nearest dummy column generates DL1 signal, which signal is buffered to latch enable (LE) signal in the column control signal. Thus LE signal enables all the read data latches to measure the current flow from the memory cells. After measuring all the memory cells, the farthest dummy column generates DL2 signal, which signal enables to raise output enable (OE) signal in order to transfer the read output Oi to the output data bus, and disables RD signal to cut the read current path to reduce current of the dummy columns while man columns are already cut off by the self-closing data latch. During read cycle, the current mirror repeats the memory cell current and latches the cell data. After latching data, the current path is cut off by the feedback output, where the current paths of each bit line are expressed iBLi and iBLi+N. And then, OE signal of the farthest dummy column becomes DOE signal, (as shown 1013 in FIG. 10), which disables the word line and dummy word line. By resetting the dummy word line DWL, PT signal is asserted to VH level, and PB signal is asserted VL level, which signals resets all the pre-charge state for the next cycle. During read, write signals are not asserted, such as A1, F1B, F2B, FEi, DL4, WT, WB, ST and SB signal. After read, the stored data not changed.

In FIG. 12B, more detailed write operation is illustrated with timing diagram. During write cycle, WEB signal is asserted to VL level. And ACT signal is asserted to VH level to activate the memory cell, the word line WLi and the dummy word line DWL are selected, and LE, DL1, DL2 and RD signals are also asserted. But OE signal is not asserted. Instead of OE signal, WT signal is asserted to VH level. After latching data from the memory cell, the data latch stores the stored data for the write-back. After then, reset operation is executed for set operation as explained above, which raises the word line to VP level and also raises the storage nodes to VH level. And then, set (ST) signal is asserted to VH level to set data to “1” or “0”. At the far end of the column generates DL3 signal. After DL3 signal is generated, the word line WLi and the dummy word line DWL are de-asserted to VL level. After DWL signal is de-asserted to VL level, ST signal is de-asserted to VL level, PT signal is returned to VH level to reset the pre-charge nodes, and PB signal is returned to VL level to reset all the pre-charge nodes for the next cycle.

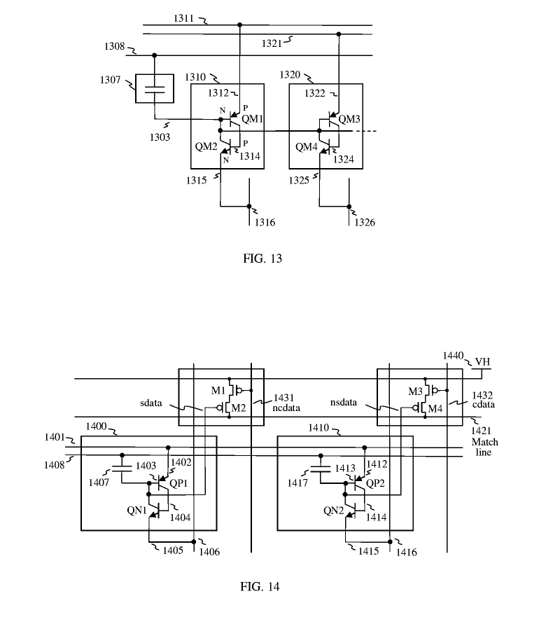

In FIG. 13, an example of multi-port memory application is illustrated as the present invention, wherein multiple diode access devices share a capacitor storage element 1307. The diode 1310 and 1320 are independently accessed, which means that two diodes are connected by a metal line 1303 including ohmic contact, in order to remove p-n diode effect. Thus there is no interference when one of the diode is activated by the word line 1311 or 1321, because the storage node 1303 is reverse-biased for the unselected diode, as long as unselected word line and bit line keep ground level. In doing so, many diode access devices can be connected to a capacitor storage element. The multi-port memory is configured such that the emitter 1312 of p-n-p QM1 is connected to the word line 1311, the base of p-n-p QM1 is connected to the storage node 1303 which is connected to one electrode of the capacitor 1307 and the another electrode of the capacitor 1307 is connected to the plate line 1308, the collector 1314 of p-n-p QM1 serves as the base of n-p-n QM2, the emitter 1315 of n-p-n QM2 is connected to the first the bit line 1316, the collector 1324 of p-n-p QM3 serves as the base of n-p-n QM4, and the emitter 1325 of n-p-n QM4 is connected to the second the bit line 1326. The read and write operation are the same as that of single port RAM as explained above, but unselected word line and bit line keep VL level while selected word line and bit line are moving. The current flow is set up from the selected word line to the selected bit line when the stored data is “1”, otherwise the diodes are turned off.

Additionally, in FIG. 14, an example embodiment to implement CAM (content addressable memory) using the capacitor storage memory as the present invention is illustrated. There are two memory cells and two compare circuits in a CAM cell. Read-write operation for the memory cells is the same as single port memory as explained above. And CAM operation is added in order to compare the stored data and the incoming data referred as comparand. In detail, a CAM is a storage device that is particularly suitable for matching functions because it can be instructed to compare a specific pattern of comparand data with data stored in an associative CAM array. A CAM can include a number of data storage locations, each of which can be accessed by a corresponding address. Functionality of a CAM depends at least in part on whether the CAM includes binary or ternary CAM cells. Ternary CAM cells are mask-per-bit CAM cells that effectively store three states of information, namely a logic “1” state, a logic “0” state, and a don't care state for compare operations. Ternary CAM cells typically include a second memory cell that stores local mask data for the each ternary CAM cell. The local mask data masks the comparison result of the comparand data with the data stored in the first memory cell such that, when the mask bit has a first predetermined value (a logic “0”, for example) its compare operation will be masked so that the comparison result does not affect the match line. The ternary CAM cell offers more flexibility to the user to determine on an entry-per-entry basis which bits in a word will be masked during a compare operation. There are prior arts using DRAM, “DRAM based refresh-free ternary CAM”, U.S. Pat. No. 6,331,961. But DRAM needs refresh to sustain data, which makes the system complicated. And another prior art is shown using negative differential resistance device, “Semiconductor capacitively-coupled negative differential resistance device and its applications in high-density high-speed memories and in power switches”, U.S. Pat. No. 6,229,161. As explained above, p-n-p-n diode itself (thyristor, or negative differential resistance device) can not be used as a storage element while the present invention uses the p-n-p-n diode as an access device, not storage device. And conventional SRAM-based CAM is used only for low-density applications. Thus the capacitor storage is used for the CAM application, which realizes high-density and high-speed nonvolatile CAM.

Detailed schematic is illustrated as shown in FIG. 14. The memory cell 1400 and 1410 store data in the storage node 1403 and 1413 which are connected to the capacitor storage 1407 and 1417, respectively. The plate line 1408 is connected to the plate of the capacitor 1407 and 1417. The storage node 1403 and 1413 serve as the bases of p-n-p QP1 and QP2 respectively. The emitter 1402 and 1412 are connected to the word line 1401. The base 1404 of n-p-n QN1 and the base 1414 of n-p-n QN2 serve as the collectors of p-n-p QP1 and p-n-p QP2, respectively. The emitter 1405 of n-p-n QN1 and 1415 of n-p-n QN2 serve as the bit line 1406 and 1416, respectively. Compare circuit including PMOS M1 and M2, M3 and M4 share a match line 1421 (ML).

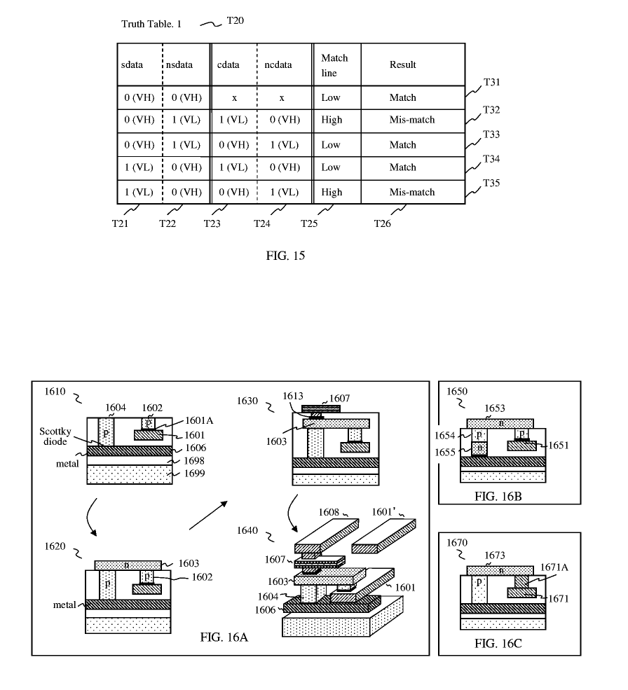

Referring now to FIG. 15 in view of FIG. 14, a truth table T20 is shown summarizing the behavior of CAM cell in relation to signal states maintained by various elements within CAM cell in accordance with the present invention, wherein the compare circuits are configured by the PMOS M1 to M4. Thus, the signal polarity of the internal nodes are inverted, such that VH level is provided by the logic “0”, and VL level is provided by the logic “1” in order to turn on the match line through the PMOS. All the internal polarities are revered from the NMOS type compare circuit (not shown) which is familiar to analyze it. First column T21 lists binary states of “0” (at VH) and “1” (at VL) that can be stored in storage node of the memory cell 1400; second column T22 lists binary states of “0” (at VH) and “1” (at VL) that can be stored in storage node of the memory cell 1410. Third column T23 lists the ternary states that can be maintained in one of the complement compare data lines, namely cdata which is the signal 1432. Fourth column T24 lists the ternary states that can be maintained in the other complement compare data line, namely ncdata which is the signal 1431. Fifth column T25 lists “low (negated logic)” and “high” as the two available voltage levels for match line ML. Finally, sixth column T26 lists “match” and “mismatch” as the two possible results for comparing states of ncdata line 1431 and cdata line 1432 with the states of CAM cell.

Continuing with FIG. 14 in view of FIG. 15, row T31 indicates masked case where sdata and nsdata are “0” (at VH) which makes match line to stay the pre-charge level (“low), regardless of the compare data, such that the stored data “0” has potential VH level which turns off PMOS compare circuit M2 and M4, rows T32-T33 both indicate that “0” state of CAM cell is represented by “0” (at VH) of capacitor memory cell 1400, and “1” (at VL) of capacitor memory cell 1410. In row T32, because state “1” of cdata line 1432 does not match state “0” of CAM cell, match line ML is driven “high (negated logic)” to indicate a mismatch of the data key and the stored value (state “0” at VH) of CAM cell. In row T33, because state “0” (at VH) of cdata line 1432 matches state “0” (at VH) of CAM cell, match line ML is driven “low” to indicate a partial match of the comparand and the stored value (state “0”, at VH) of CAM.

Continuing still with FIG. 15 in view of FIG. 14, rows T34-T35 both indicate that “1” state of CAM cell is represented by “1” (at VL) of capacitor memory cell 1400 and “0” (at VH) of capacitor cell 1410. In row T34, because state “1” (at VL) of cdata line 1432 matches state “1” (at VL) of CAM cell, match line ML is driven “low (negated logic)” to indicate a partial match of the comparand and the stored value (state “1”, at VL) of CAM cell. In row T35, because state “0” (at VH) of cdata line 1432 does not match state “1” (at VL) of CAM cell, match line ML is driven “high (negated logic)” to indicate a mismatch of the comparand and the stored value (state “1”, at VL) of CAM cell.

### Methods of Fabrication

Replacing MOS access device with a diode access device, the memory cell needs only a p-n-p-n diode (or n-p-n-p diode) and a storage element, which realizes stacked type of memory cell structure, in order to reduce chip area. This also realizes fast access time with shorter routing delay. The steps in the process flow should be compatible with the current CMOS manufacturing environment, which are reported as the prior arts, such as U.S. Pat. No. 6,104,045, No. 6,229,161, No. 6,940,761, and No. 6,943,083. In this respect, there is no need of describing too much detailed process flow to form the memory cell, such as width, length, thickness, temperature, forming method or any other material related data. Instead of describing those details, the present invention focuses on illustrating the new memory cell structures which are practical and mass producible.

The invented capacitor memory cell has a capacitor and a diode, which is simple to fabricate on the wafer, as long as the reverse bias leakage and the oxide leakage are controllable. And the other leakage path through the substrate is removed, which is called back channel effect when the memory cell is formed on surface of the wafer, as published, Chen et al, “Characterization of back-channel subthreshold conduction of walled SOI devices”, IEEE Transactions on electron Devices, Vol. 38, No. 12, pp. 2722, December 1991, and Shin et al, “Leakage current models of thin film silicon-on-insulator devices”, Applied Physics Letters, Vol. 72, No. 10, March 1998. In the present invention, the memory cell is formed in between the routing layers, thus there is no relation to the bulk or substrate. Furthermore, the memory cell is formed after the MOS transistors are fabricated. In this manner, the memory cell process is independent of the MOS transistor process. Hence, topping the memory cells with low temperature can be available with amorphous silicon or polysilicon.

In order to form the diode on the metal routing layer, LTPS (Low Temperature Polysilicon) can be used to form the diode, as published, U.S. Pat. No. 5,395,804, U.S. Pat. No. 6,852,577 and U.S. Pat. No. 6,951,793. LTPS has been developed for the low temperature process (500 Celsius or lower) on the glass in order to apply the display panel, according to the prior arts. Now the LTPS can be used as a diode for the memory access device. Generally, polysilicon diode can flow less current than single crystal silicon diode, but the polysilicon diode can flow more current than MOS transistor, because the diode can flow the current through the whole junction while the MOS transistor can flow the current through the shallow inversion layer by the gate control. In the present invention, LTPS-based diode is useful to stack the diode-based memory cells with no very thin oxide layer, because the memory cell does not include MOS transistor. The insulator for the storage capacitor may be thicker than that of MOS transistor. For example, ferroelectric capacitor can provide more capacitance with slightly thick layer. During polysilicon process, the MOS transistor in the control circuit and routing metal are less degraded.

In FIG. 16A, brief process steps to form stacked capacitor memory on the wafer are illustrated, as the present invention. As shown in the structure 1610, the metal bit line 1606 is formed after adding the isolation layer 1698 on the wafer 1699, and then the metal word line 1601 is formed. After then, the p-type third terminal 1604 is formed and makes Schottky diode with the metal bit line 1606. And then, p-type first terminal 1602 is formed on the silicide 1601A which forms an ohmic contact to reduce contact resistance. After the, n-type region 1603 is deposited as shown in the structure 1620. As a result, p-n-p-diode is formed on the metal bit line and the metal word line. After forming the diode, the storage capacitor 1607 is formed on the contact region 1613 which is connected to the second terminal 1603, as shown in the structure 1630, wherein the storage capacitor 1607 may include single or multiple dielectric layers in order to get more capacitance, and various materials can be used as electrode with buffer layer. Alternatively, series capacitor is available in order to get more yield, such that one more capacitor is formed on the storage capacitor in series (not shown), with the same or similar process. In consequence, the structure 1640 is completed, wherein the plate line 1608 is formed on the capacitor 1607 and a passing line 1601′ is formed. The passing line 1601′ can be used as a global word line or a global plate line.

In FIG. 16B, an alternative cell structure 1650 is illustrated, as the present invention, wherein Schottky diode is removed by adding n-type region 1655 on the metal bit line with ohmic contact, which can be formed before forming the metal word line 1651. Alternatively, as shown 1670 in FIG. 16C, more cell structures are illustrated, wherein the plug region 1671A can be metal plug and forms another Schottky diode with the second terminal 1673.

In FIG. 17, an example cell structure on the MOS transistor is illustrated, as the present invention. The structure of the memory cell is the same structure 1640 in FIG. 16A, which can be formed on the MOS transistor in order to reduce cell area. The process step of the memory cell is independent of MOS transistor process because the memory cell does not include MOS transistor. Hence, the memory cell does not include very thin layers. On the contrary, the memory cell uses relatively thick layers to form capacitor and diode, which are also formed at low temperature in general. The low temperature process does not degrade MOS transistor characteristics. The metal bit line 1706 is formed after forming MOS transistor on the SOI wafer, the bit line 1706 is connected to the drain 1732 of MOS transistor, and the gate 1731 including silicide layer controls the drain 1706 and the source 1733, for example, where the body 1734 is isolated from the substrate 1799 by the buried oxide 1798, and the drain 1732 is also isolated by the STI (Shallow Trench Isolation) region. In order to form the memory cell between the routing layers, the routing layer (the word line 1701) is formed after forming the bit line 1706. After then the routing layer 1735 is formed. And p-type region (third terminal) 1704 is vertically formed after forming routing layer 1735, which becomes Schottky diode, and then another p-type region (first terminal) 1702 is vertically formed with silicide layer to make ohmic contact. And n-type (second terminal) 1703 is formed after completing the first terminal 1702. Then capacitor 1707 is formed. In this manner, the memory cells are formed in between the routing layer.

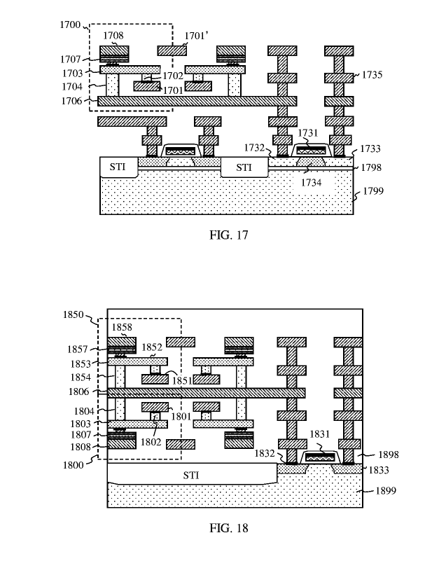

In FIG. 18, stacked memory cells on the bulk are illustrated, as the present invention, wherein the plate 1808 in the lower memory cell 1800 is isolated from the bulk 1899 (by the isolation layer 1898), the storage capacitor 1807 is formed on the plate line 1808, the second terminal 1803 is connected to the storage capacitor 1807 and connected to the third terminal 1804, the second terminal 1803 is also attached to the first terminal 1802, the first terminal 1802 is connected to the word line 1801 with ohmic contact, and the third terminal 1804 is vertically attached to the metal bit line 1806 and forms Schottky diode. The upper memory cell 1850 is formed and mirrored on the lower memory cell, wherein the third terminal 1854 is vertically attached to the metal bit line 1806 and forms Schottky diode, the third terminal 1854 is vertically attached to the second terminal 1853, the second terminal 1853 is vertically attached to the first terminal 1851 and the storage capacitor 1857, and the plate line 1858 is connected to the storage capacitor 1857. The bit line 1806 is shared with the lower cell 1800 and the upper cell 1850.

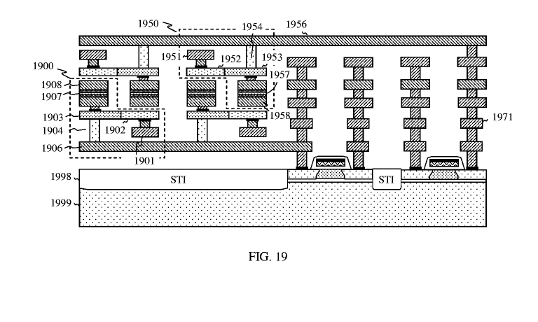

In FIG. 19, another stacked memory cell on the SOI wafer is illustrated, as the present invention, wherein the capacitor is formed at one time, thus the capacitor forming step is reduced. The lower cell 1900 is configured, such that the bit line 1906 is formed on the wafer after forming MOS transistor, and then the word line 1901 is formed, after then the routing layer 1971 is formed. After then, the p-type third terminal 1904 is plugged to the metal bit line 1906 and forms Schottky diode, and then the first terminal (p-type region) 1902 is formed on the word line 1901 with ohmic contact. After then, the n-type second terminal 1903 is deposited, and then, p-type first terminal 1902 is implanted by the p-type ions. In doing so, the second terminal 1903 has no coupling region to the plate line of the upper memory cell, which is important to isolate the second terminal 1903 from the coupling, because the second terminal serves as a storage node which is charged to store data. The capacitor 1907 is formed on the second terminal 1903. And the plate line 1908 is formed on the capacitor 1907. The upper memory cell 1950 is formed reverse order, wherein the capacitor 1857 is vertically formed on the plate line 1958, the second terminal 1953 is vertically attached to the capacitor 1857, the word line 1951 is vertically connected to the first terminal 1952, the first terminal 1952 is vertically attached to the second terminal 1953, the third terminal 1954 is vertically attached to the second terminal 1953, and the bit line 1956 is attached to the third terminal 1954 with Schottky diode. In this structure, the capacitor process is reduced and the bit lines are separately connected, thus parasitic capacitance of the bit line is reduced, which achieves fast switching of the bit line. As a result, high-speed operation is realized. And also high-density memory is realized with the stacked structure.

While the description here has been given for configuring the memory circuit and array, alternative embodiments would work equally well with reverse connection, wherein n-p-n-p diode serves as an access device, the first terminal is n-type and connected to the word line, the second terminal is p-type and connected to the storage node, the third terminal is n-type and floating, and the fourth terminal is p-type and connected to the bit line. Signal polarities are reversed as well, wherein active high signal works as active low signal for the reverse configuration, and supply voltage of the word line is lower that that of the bit line while supply voltage of the word line is higher that that of the bit line when p-n-p-n diode serves as an access device as explained above.

The foregoing descriptions of specific embodiments of the invention have been presented for purposes of illustration and description. They are not intended to be exhaustive or to limit the invention to the precise forms disclosed. Obviously, many modifications and variations are possible in light of the above teaching. The embodiments were chosen and described in order to explain the principles and the application of the invention, thereby enabling others skilled in the art to utilize the invention in its various embodiments and modifications according to the particular purpose contemplated. The scope of the invention is intended to be defined by the claims appended hereto and their equivalents.

What is claimed is:

1. A memory device, comprising:
memory cell, wherein a capacitor stores data and a diode serves as an access device; and the capacitor includes two electrodes, one electrode serves as a storage node, and another electrode is connected to a plate line; and the diode, wherein includes four terminals, the first terminal is connected to a word line, the second terminal is connected to the storage node, the third terminal is floating, and the fourth terminal is connected to a bit line; and the memory cell is formed in between the routing layers on the wafer; and
memory cell array, wherein includes main memory cells and dummy memory cells, main memory cells configure main columns, dummy memory cells configure dummy row(s) and dummy column(s), dummy row(s) generates delayed signal based on the dummy word line, dummy column(s) generates delayed signal based on the dummy column; and
data latch, wherein includes current mirror and latch circuit, the current mirror is connected to the diode through the bit line and the latch circuit is connected to the current mirror, and the latch circuit cuts off the current path of the bit line after latching data from the memory cell; and
dual positive supplies are used for the memory cell array and the data latch, wherein the word line is driven by the word line driver which is powered by the first positive supply, and the data latch is powered by the second positive supply, and wherein the first positive supply is higher than the second positive supply.

2. The memory device of claim 1, wherein the diode includes four terminals, the first terminal is p-type, the second terminal is n-type, the third terminal is p-type, and the fourth terminal is n-type.

3. The memory device of claim 1, wherein the diode includes four terminals, the first terminal is n-type, the second terminal is p-type, the third terminal is n-type, and the fourth terminal is p-type.

4. The memory device of claim 1, wherein at least one terminal of the diode includes metal to form Schottky diode.

5. The memory device of claim 1, wherein the diode is formed from silicon including polysilicon, amorphous silicon, and stretchable silicon.

6. The memory device of claim 1, wherein the diode is formed from germanium.

7. The memory device of claim 1, wherein the diode is formed from compound semiconductor.

8. The memory device of claim 1, wherein the capacitor includes ordinary dielectric capacitor or ferroelectric dielectric capacitor.

9. The memory device of claim 1, wherein the capacitor includes series capacitor.

10. The memory device of claim 1, wherein at least one terminal of the diode is vertically formed on the other terminal of the diode.

11. The memory device of claim 1, wherein the memory cells are formed on the MOS transistor.

12. The memory device of claim 1, wherein the memory cells are formed on the bulk wafer.

13. The memory device of claim 1, wherein the memory cells are formed on the SOI wafer.

14. The memory device of claim 1, wherein two memory cells are stacked on the wafer.

15. The memory device of claim 1, wherein the current mirror in the data latch includes lower threshold MOS transistor than that of control circuit in the chip.

16. The memory device of claim 1, wherein the current mirrors are connected to a ground line which is in the opposite side of the word line driver (row decoder).

17. The memory device of claim 1, wherein multiple diode access devices share a capacitor, in order to configure multi port memory.

18. A content addressable memory, comprising: at least one memory cell including capacitor storage element and four-terminal diode access device; and at least one compare circuit coupled among the memory cell and at least one match line to receive first and second signal sets and affect a logical state of the match line in response to a predetermined logical relationship between the first and second signal sets, the compare circuit including a first transistor set and a second transistor set, wherein the first signal set couples to control a conduction state of the first transistor set and the second signal set couples to control a conduction state of the second transistor set, wherein the first signal set includes stored data and the second signal set includes comparand data.
